(19) United States
(12) Patent Application Publication
(10) Pub. No.: US 2025/0194102 A1
(43) Pub. Date: Jun. 12, 2025

(54) SEMICONDUCTOR DEVICE INCLUDING A SELECTOR AND A METHOD OF FABRICATING A SEMICONDUCTOR DEVICE

(71) Applicant: SK hynix Inc., Icheon-si (KR)

(72) Inventors: Cha Deok DONG, Icheon-si (KR); Jeong Myeong KIM, Icheon-si (KR); Keo Rock CHOI, Icheon-si (KR)

(21) Appl. No.: 18/823,570

(22) Filed: Sep. 3, 2024

(30) Foreign Application Priority Data
Dec. 12, 2023 (KR) 10-2023-0179471

(51) Int. Cl. H10B 61/00

(52) U.S. Cl. CPC H10B 61/10

(57) ABSTRACT

A method for fabricating a semiconductor device includes: forming a first electrode layer; forming, over the first electrode layer, a plurality of dielectric layers with one or more metal-containing patterns or one or more metal-containing thin films being disposed between at least two neighboring dielectric layers of the plurality of dielectric layers; and forming a selector layer by performing a first implanting process to implant a dopant into the at least two neighboring dielectric layers including or in contact with the one or more metal-containing patterns or the one or more metal-containing thin films.

### CROSS-REFERENCE TO RELATED APPLICATIONS

The patent document claims the priority and benefits of Korean Patent Application No. 10-2023-0179471, filed on Dec. 12, 2023, which is incorporated herein by reference in its entirety.

### TECHNICAL FIELD

The technology disclosed in this patent document relates to a semiconductor device including a selector, and a method of fabricating a semiconductor device.

### BACKGROUND

With the recent trend toward miniaturization, low-power consumption, high performance, and diversification in the electrical and electronics industry, the importance of semiconductor devices that may store data in diverse electronic devices, such as computers and portable communication devices, is increasing. Such semiconductor devices include semiconductor memory devices that may store data by using the characteristic of switching between different resistance states according to the applied voltage or current, for example, resistive random access memory (RRAM), phase-change random access memory (PRAM), a ferroelectric random access memory (FRAM), magnetic random access memory (MRAM), and electronic fuse (E-fuse).

### SUMMARY

The disclosed technology can be implemented in some embodiments to provide a semiconductor device that may secure the characteristics of a selector, and a method for fabricating the same.

In an embodiment of the disclosed technology, a method of fabricating a semiconductor device includes forming a first electrode layer; forming, over the first electrode layer, a plurality of dielectric layers with one or more metal-containing patterns or one or more metal-containing thin films being disposed between at least two neighboring dielectric layers of the plurality of dielectric layers; and forming a selector layer by performing a first implanting process to implant a dopant into the at least two neighboring dielectric layers including or in contact with the one or more metal-containing patterns or the one or more metal-containing thin films. In some implementations, the plurality of dielectric layers with one or more metal-containing patterns or one or more metal-containing thin films can be formed by stacking the plurality of dielectric layers and the one or more metal-containing patterns or one or more metal-containing thin films in a certain order.

In another embodiment of the disclosed technology, a semiconductor device includes a first electrode layer; and a selector layer configured to exhibit a threshold switching behavior and disposed over the first electrode layer. In some implementations, the selector layer includes a dielectric layer, a dopant configured to form a trap site that provides a passage for conductive carriers in the dielectric layer, and metal ions distributed in the dielectric layer.

### BRIEF DESCRIPTION OF THE DRAWINGS

FIG. 1 is a perspective view illustrating a semiconductor device based on an embodiment of the disclosed technology.

FIGS. 2A and 2B are cross-sectional views illustrating a method for forming a selector unit based on an embodiment of the disclosed technology.

FIGS. 3A and 3B are cross-sectional views illustrating a method for forming a selector unit and the selector unit formed accordingly based on another embodiment of the disclosed technology.

FIG. 3C is a cross-sectional view illustrating a selector unit based on another embodiment of the disclosed technology.

FIGS. 4A and 4B are cross-sectional views illustrating a method for forming a selector unit and the selector unit formed accordingly based on another embodiment of the disclosed technology.

FIG. 4C is a cross-sectional view illustrating a selector unit based on another embodiment of the disclosed technology.

FIGS. 5A and 5B are cross-sectional views illustrating a method for forming a selector unit and the selector unit formed accordingly based on another embodiment of the disclosed technology.

FIGS. 6A to 6C are cross-sectional views illustrating a method for forming a selector unit and the selector unit formed accordingly based on another embodiment of the disclosed technology.

FIGS. 7A and 7B are cross-sectional views illustrating a method for forming a selector unit and the selector unit formed accordingly based on another embodiment of the disclosed technology.

### DETAILED DESCRIPTION

Embodiments of the disclosed technology will be described below in more detail with reference to the accompanying drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Hereinafter, the various embodiments of the disclosed technology will be described in detail with reference to the attached drawings.

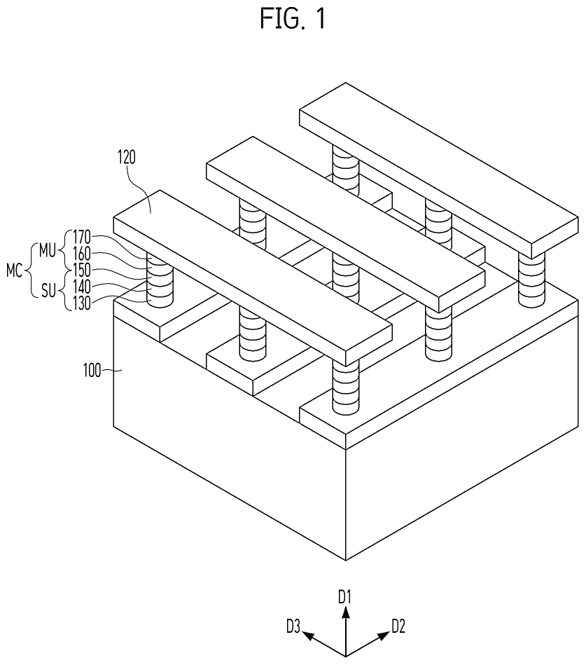

FIG. 1 is a perspective view illustrating a semiconductor device based on an embodiment of the disclosed technology.

Referring to FIG. 1, a semiconductor device of this embodiment of the disclosed technology may include a substrate 100, a plurality of first conductive lines 110, a plurality of second conductive lines 120, and a plurality of memory cells MC. In some embodiments of the disclosed technology discussed below, a first direction (D1) may be substantially perpendicular to a surface of the substrate 100, and second and third directions D2 and D2 may substantially parallel to the surface of the substrate 100. The second direction D2 and the third direction D3 may cross each other, for example, the second direction D2 and the third direction D3 may be perpendicular to each other.

The substrate 100 may include a semiconductor material, such as a silicon wafer. In some embodiments, a lower structure (not shown) such as an integrated circuit for driving (e.g., control, select, activate, etc.) the first conductive line 110 and/or the second conductive line 120 may be formed in and/or on the substrate 100.

The plurality of first conductive lines 110 may be disposed over the substrate 100. The first conductive lines 110 may extend in the second direction D2 and may be arranged to be spaced apart from each other in the third direction D3. The first conductive lines 110 may include diverse conductive materials, for example, a metal such as platinum (Pt), tungsten (W), aluminum (Al), copper (Cu), tantalum (Ta) and the like, a metal nitride such as titanium nitride (TiN), tantalum nitride (TaN) and the like, or a combination thereof, and the first conductive lines 110 may have a single-layer structure or a multi-layer structure.

The plurality of second conductive lines 120 may be disposed to be spaced apart from the first conductive lines 110 over the first conductive lines 110. The second conductive lines 120 may extend in the third direction D3 and may be arranged to be spaced apart from each other in the second direction D2. The second conductive lines 120 may include diverse conductive materials, for example, a metal such as platinum (Pt), tungsten (W), aluminum (Al), copper (Cu), tantalum (Ta) and the like, a metal nitride such as titanium nitride (TiN), tantalum nitride (TaN) and the like, or a combination thereof, and the second conductive lines 120 may have a single-layer structure or a multi-layer structure.

The plurality of memory cells MC may be arranged to overlap with the intersection areas between the first conductive lines 110 and the second conductive lines 120. Each of the memory cells MC may include a memory unit MU configured to store data, and a selector unit SU, which controls access to the memory unit MU. For example, each of the memory cells MC may include a stacked structure that includes a lower electrode layer 130, a selector layer 140, a middle electrode layer 150, a variable resistance layer 160, and an upper electrode layer 170. Here, the selector unit SU may include the lower electrode layer 130, the selector layer 140, and the middle electrode layer 150, and the memory unit MU may include the middle electrode layer 150, the variable resistance layer 160, and the upper electrode layer 170. The middle electrode layer 150 may be shared by the selector unit SU and the memory unit MU.

The lower electrode layer 130 and the upper electrode layer 170 may be disposed at first and second ends of the memory cell MC, for example, at a bottom end and a top end of the memory cell MC, respectively, and may transfer the voltage or current for the operation of the memory cell MC. The middle electrode layer 150 may electrically connect the selector layer 140 to the variable resistance layer 160 while physically separating them from each other. The lower electrode layer 130, the middle electrode layer 150, or the upper electrode layer 170 may include diverse conductive materials, for example, a metal such as platinum (Pt), tungsten (W), aluminum (Al), copper (Cu), tantalum (Ta), titanium (Ti) and the like, a metal nitride such as titanium nitride (TiN), tantalum nitride (TaN) and the like, or a combination thereof. In some implementations, the lower electrode layer 130, the middle electrode layer 150, or the upper electrode layer 170 may include a carbon electrode.

The selector layer 140 may prevent current leakage that may occur between the memory cells MC which share the first conductive line 110 or the second conductive line 120, while controlling the access to the variable resistance layer 160 within each memory cell MC. To this end, the selector layer 140 in each memory cell MC may exhibit threshold switching characteristics between different states of electrical conductivity, including: (1) an electrically non-conducting state that blocks flow of a current through the selector layer 140 or allows a very small amount of the current to flow when the level of the voltage supplied to the top and bottom portions of the selector layer 140 is lower than a predetermined threshold voltage, and (2) an electrically conducting state that allows for electrical conduction so that the current begins to flow through the selector layer 140 and increases rapidly when the level of the voltage supplied to the top and bottom portions of the selector layer 140 is equal to or higher than the threshold voltage. Accordingly, by controlling the voltage supplied to the selector layer 140, the selector layer 140 may be turned on to be in the electrically conducting state at a supplied voltage level of the threshold voltage or higher, and may be turned off to be at the electrically non-conducting state at a supplied voltage level lower than the threshold voltage.

In various implementations, the selector layer 140 may include an Ovonic Threshold Switching (OTS) material, such as a diode and a chalcogenide-based material, a Mixed Ionic Electronic Conducting (MIEC) material, such as a metal-containing chalcogenide-based material, a Metal-Insulator Transition (MIT) material, such as NbO₂, VO₂ and the like, or a tunneling dielectric material with a relatively wide band gap, such as SiO₂, Al₂O₃ and others.

In some implementations, the selector layer 140 may include a dielectric material containing a dopant implanted through an ion implantation process. In one example, the dielectric material may include a silicon-containing dielectric material, such as silicon oxide, silicon nitride, silicon oxynitride and others, a dielectric metal oxide, a dielectric metal nitride, or a combination thereof. The dopant may serve to capture conductive carriers migrating in the dielectric material or to create trap sites that provide a passage for the captured conductive carriers to migrate again. To form the trap sites, diverse elements that may create energy potentials capable of accommodating the conductive carriers in the dielectric material may be used as the dopant. For example, when the dielectric material includes a silicon-containing dielectric material, the dopant may include a metal whose valence is different from that of silicon, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof. Also, when the dielectric material includes a dielectric metal oxide or a dielectric metal nitride, the dopant may include a metal whose valence is different from the valence of the metal of the metal oxide or metal nitride, or silicon. For example, the selector layer 140 may include silicon dioxide (SiO₂) into which arsenic (As) is implanted through an ion implantation method. When a voltage equal to or higher than the threshold voltage is applied to the selector layer 140, the conductive carriers may migrate through the trap sites, and the selector layer 140 is at an “on” state to allow current to flow through the selector layer 140. When the voltage applied to the selector layer 140 is reduced to a level that is lower than the threshold voltage, the selector layer 140 transitions to an “off” state to allow no conductive carriers to move and thus no current flows.

The variable resistance layer 160 may be a portion of the memory cell MC that functions to store data. To this end, the variable resistance layer 160 may exhibit variable resistance characteristics that switch between different resistance states according to the applied voltage. The variable resistance layer 160 may have a single-layer structure or a multi-layer structure including diverse materials used in a resistive random access memory (RRAM), a phase-change random access memory (PRAM), a ferroelectric random access memory (FRAM), a magnetic random access memory (MRAM) and others, such as transition metal oxides, metal oxides such as perovskite-based materials, phase-change materials such as chalcogenide-based materials, ferroelectric materials, ferromagnetic materials and the like. When the variable resistance layer 160 has a high resistance state, the data bit stored in the memory cell MC may correspond to “0,” and when the variable resistance layer 160 has a low resistance state, the data bit stored in the memory cell MC may correspond to “1.”

This memory cell MC may have a pillar shape that overlaps with the intersection area of the first conductive line 110 and the second conductive line 120. Although FIG. 1 illustrates the memory cell MC as having a cylindrical shape, the disclosed technology is not limited thereto, and the memory cell MC may have a shape different from the cylindrical shape, such as a square pillar or an elliptical pillar. In some implementations, the layers 130 to 170 forming the memory cell MC are illustrated to have sidewalls that are aligned with each other by being patterned using one mask, but the disclosed technology is not limited thereto. In some implementations, when the variable resistance layer 160 has a multi-layer structure such as a magnetic tunnel junction structure, it may be difficult to collectively etch the layers 130 to 170 that constitute the memory cell MC. In this case, the selector layer 140 and the variable resistance layer 160 may be patterned separately by using different etch masks, and in this case the selector layer 140 and the variable resistance layer 160 may include sidewalls that are not aligned with each other. The lower electrode layer 130 and the middle electrode layer 150 may be patterned together with the selector layer 140, and the upper electrode layer 170 may be patterned together with the variable resistance layer 160.

In some implementations, the layer structure of the memory cell MC is not limited to the illustrated layer structure, and the stacking order of the layers may be changed, or one or more of the layers may be omitted, or one or more layers may be added. For example, one or more among the lower electrode layer 130, the middle electrode layer 150, and the upper electrode layer 170 may be omitted. In some implementations, the locations of the selector layer 140 and the variable resistance layer 160 may be switched. In other words, the selector layer 140 may be disposed over the middle electrode layer 150, and the variable resistance layer 160 may be disposed below the middle electrode layer 150. In some implementations, one or more layers (not shown) may be added to the memory cell MC to improve the process or the characteristics of the memory cell MC.

As will be explained below, the disclosed technology can be implemented in some embodiments to provide a method for forming a selector unit to improve the characteristics of the selector unit in the semiconductor device and the selector unit. In some implementations, the selector layer of the selector unit is formed by implanting a dopant into a dielectric material, as will be described below.

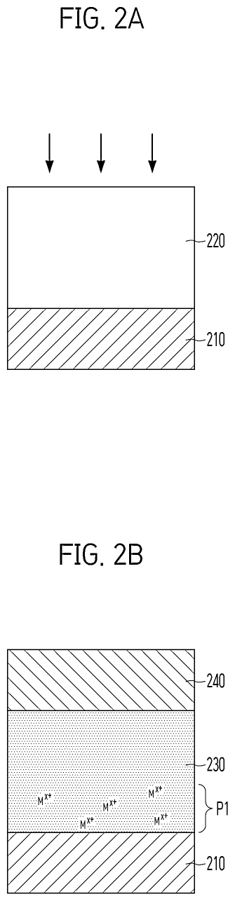

FIGS. 2A and 2B are cross-sectional views illustrating a method for forming a selector unit based on an embodiment of the disclosed technology.

Referring to FIG. 2A, a first electrode layer 210 may be provided or formed. The first electrode layer 210 may substantially correspond to the lower electrode layer 130 of FIG. 1, as described above.

Subsequently, a dielectric layer 220 may be formed over the first electrode layer 210. The dielectric layer 220 may function as a matrix for forming a selector and may be formed through a deposition process. For example, the dielectric layer 220 may include a silicon-containing dielectric material, such as silicon oxide, silicon nitride, silicon oxynitride and the like, a dielectric metal oxide, a dielectric metal nitride, or a combination thereof. In some implementations, the dielectric layer 220 may include silicon dioxide.

Subsequently, a dopant may be implanted into the dielectric layer 220. Ion implantation may be performed in a direction from the vertical direction toward the dielectric layer 220, that is, in a direction from top to bottom (see an arrow in FIG. 2A). The dopant may create trap sites that provide a passage for conductive carriers migrating in the dielectric layer 220, for example, electrons or holes. The dopant may include an element whose valence is different from that of the element of the dielectric layer 220, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination of. When the dielectric layer 220 includes silicon dioxide, the dopant may include arsenic.

The dielectric layer containing the dopant implanted through an ion implantation process may form the selector layer 230, which is illustrated in FIG. 2B.

Referring to FIG. 2B, the selector layer 230 may be formed over the first electrode layer 210. The selector layer 230 may substantially correspond to the selector layer 140 of FIG. 1.

Subsequently, a second electrode layer 240 may be formed over the selector layer 230. The second electrode layer 240 may substantially correspond to the middle electrode layer 150 of FIG. 1.

Subsequently, although not illustrated, the first electrode layer 210, the selector layer 230, and the second electrode layer 240 may be patterned to form a selector unit.

In some implementations, during the ion implantation process of the dopant, the elements of the first electrode layer 210, particularly metal ions, may be incorporated into the dielectric layer 220 and/or the selector layer 230 by using a scattering mechanism. As a result, some of the elements of the first electrode layer 210 are distributed in the dielectric layer 220 and/or the selector layer 230. In FIG. 2B, M^{x+} indicates the metal ions in the selector layer 230. For example, when the first electrode layer 210 includes titanium nitride, titanium ions of the first electrode layer 210 may be incorporated into the dielectric layer 220 and/or the selector layer 230. The incorporation of titanium nitride, titanium ions of the first electrode layer 210 into the dielectric layer 220 and/or the selector layer 230 may occur through the following mechanism. When the dielectric layer 220 includes a material (e.g., silicon dioxide) having a very large binding energy, an element having a relatively large mass and size, such as arsenic (As), may be implanted to break a bond (e.g., chemical bond) in the dielectric layer 220, and, in such a case, the arsenic ions may collide with the surface of the first electrode layer 210. These metal ions are metallic components, and when the metal ions are uniformly distributed at an appropriate concentration in the selector layer 230, the switching characteristics may be improved. For example, the switching characteristics may be improved by lowering the forming voltage/threshold voltage of the selector layer 230.

However, when metal ions are incorporated through the scattering mechanism, it may be difficult to control the concentration and distribution of metal ions. When metal ions are incorporated through the scattering mechanism, metal ions are mainly concentrated in the portion adjacent to the interface of the selector layer 230 with the first electrode layer 210, that is, in the lower portion of the selector layer 230 (see the portion P1 in FIG. 2B). In order to increase the concentration of the metal ions and uniformly distribute them in the selector layer 230, it is necessary to increase the ion implantation energy when the dopant is implanted. However, as the ion implantation energy is increased, part of the dielectric layer 220 may be lost, and it may be difficult to secure the selector layer 230 of a desired thickness. In addition, the interface between the selector layer 230 and the first electrode layer 210 may become uneven, and the switching characteristics of the selector layer 230 may be deteriorated. Also, when ion implantation energy is increased, part of the first electrode layer 210 may be lost during the ion implantation process.

The disclosed technology can be implemented in some embodiments to address these issues by enabling a uniform integration of the metal ions into the selector layer at an appropriate concentration without increasing the ion implantation energy when forming a selector unit.

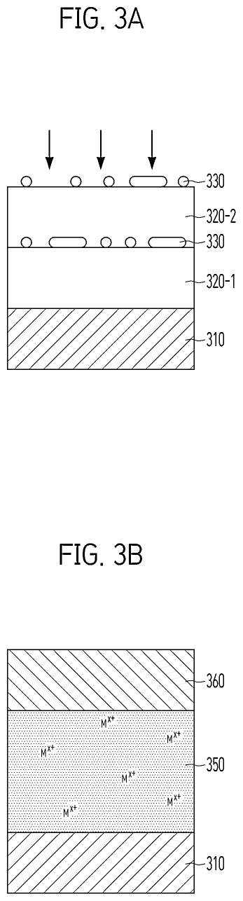

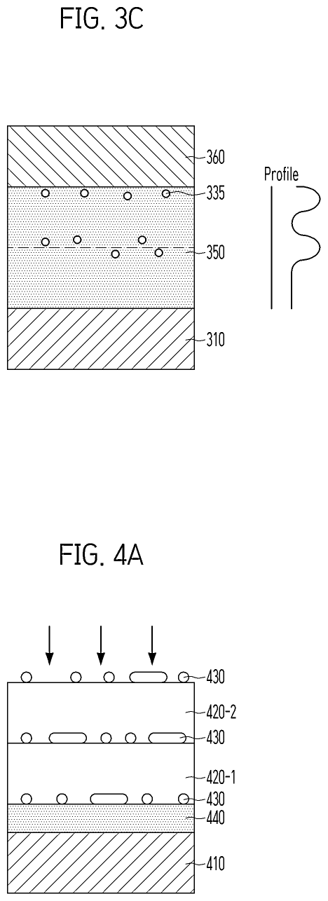

FIGS. 3A and 3B are cross-sectional views illustrating a method for forming a selector unit and the selector unit formed accordingly based on another embodiment of the disclosed technology.

Referring to FIG. 3A, a first electrode layer 310 may be provided.

Subsequently, a first dielectric layer 320-1 may be formed over the first electrode layer 310. The first dielectric layer 320-1 may be used to form at least part of a selector, and it may be formed by a deposition process. For example, the first dielectric layer 320-1 may include a silicon-containing dielectric material, such as silicon oxide, silicon nitride, silicon oxynitride and the like, a dielectric metal oxide, a dielectric metal nitride, or a combination thereof. For example, the first dielectric layer 320-1 may include silicon dioxide.

Subsequently, a metal-containing pattern 330 may be formed over the first dielectric layer 320-1. The metal-containing pattern 330 may serve as a source of metal ions. In some implementations, the metal-containing pattern 330 may correspond to a fine pattern with a size as small as a few nanometers (nm) so that it may be easily scattered during the subsequent dopant ion implantation process. The metal-containing pattern 330 may have diverse island shapes, such as a dot shape or a bar shape. The maximum length of the metal-containing pattern 330 may be several nanometers (nm). For example, the maximum length of the metal-containing pattern 330 may range from 1 to 10 nanometers. For example, when the metal-containing pattern 330 has a spherical shape or a dot shape similar to the spherical shape, it may have a diameter of several nanometers. Also, for example, when the metal-containing pattern 330 has a predetermined thickness and has a bar shape in which the length of one axis on a plane is longer than the length of another axis, the thickness and/or the maximum length on the plane may reach several nanometers. In some embodiments of the disclosed technology, the term “pattern” can be used to indicate a material layer that is formed through a patterning process using one or more masks.

The metal-containing pattern 330 may include a metal, such as tantalum (Ta), titanium (Ti), iridium (Ir), magnesium (Mg), tungsten (W), platinum (Pt) and the like, a metal oxide containing one or more of these metals, a metal nitride containing one or more of these metals, or an alloy containing two or more of these metals. Also, the metal-containing pattern 330 may be formed by a seeding process of an Atomic Layer Deposition (ALD) method using a metallic precursor, or may be formed by nucleation and growth processes of a Physical Vapor Deposition (PVD) method under the conditions that do not lead to thin film deposition, for example, low pressure, low RF power, and/or short time.

Subsequently, a second dielectric layer 320-2 may be formed over the first dielectric layer 320-1 where the metal-containing pattern 330 is formed. The second dielectric layer 320-2 may be used to form at least part of a selector and it may be formed by a deposition process. For example, the second dielectric layer 320-2 may include a silicon-containing dielectric material, such as silicon oxide, silicon nitride, silicon oxynitride and the like, a dielectric metal oxide, a dielectric metal nitride, or a combination thereof. The second dielectric layer 320-2 may include the same material as that of the first dielectric layer 320-1, such as silicon dioxide. Also, the thickness of the second dielectric layer 320-2 may be substantially the same as the thickness of the first dielectric layer 320-1. However, the disclosed technology is not limited thereto, and, in some embodiments, at least one of the material and thickness of the second dielectric layer 320-2 may be different from the first dielectric layer 320-1.

Subsequently, the metal-containing pattern 330 may be formed again over the second dielectric layer 320-2. The process conditions for forming the metal-containing pattern 330 over the first dielectric layer 320-1 and the process conditions for forming the metal-containing pattern 330 over the second dielectric layer 320-2 may be substantially the same. Even if the process conditions are same, the number, shape, and location of the metal-containing patterns 330 may vary diversely.

Although two dielectric layers 320-1 and 320-2 are formed and the metal-containing pattern 330 is formed over each of the dielectric layers 320-1 and 320-2 after each of the processes of forming the dielectric layers 320-1 and 320-2 based on some embodiments, the disclosed technology is not limited thereto. In another embodiment of the disclosed technology, a plurality of dielectric layers may be formed over the first electrode layer 310, and the metal-containing pattern 330 may be formed over each of the dielectric layers after a process of forming each of the dielectric layers. Also, considering the concentration or distribution of the metal ions, the metal-containing pattern 330 over one or more specific dielectric layers may be omitted, if necessary. In other words, when first to N^{th} dielectric layers are formed over the first electrode layer 310 (where N is a natural number equal to or greater than 2), the metal-containing pattern 330 may be formed over each of the first to N^{th} dielectric layers. In some implementations, the metal-containing pattern 330 may not be formed over a t^{th} dielectric layer among the first to N^{th} dielectric layers (where t is an arbitrary number equal to or greater than 2 and equal to or smaller than N) but may be formed over each of the remaining dielectric layers. In any case, the metal-containing pattern 330 may be formed to be disposed between at least two neighboring dielectric layers among the dielectric layers. For example, the metal-containing pattern 330 may be formed over the first dielectric layer 320-1 to be disposed between at least the first dielectric layer 320-1 and the second dielectric layer 320-2, and the metal-containing pattern 330 over the second dielectric layer 320-2 may be omitted.

Subsequently, a dopant may be implanted into the first and second dielectric layers 320-1 and 320-2 where the metal-containing pattern 330 is formed. The Ion implantation process may be performed in a direction from the vertical direction toward the first and second dielectric layers 320-1 and 320-2, e.g., in a direction from top to bottom (see an arrow in FIG. 3A). The dopant may create trap sites that provide a passage for conductive carriers migrating in the first and second dielectric layers 320-1 and 320-2, for example, electrons or holes. The dopant may be an element whose valence is different from the valences of the elements of the first and second dielectric layers 320-1 and 320-2, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof. When the first and second dielectric layers 320-1 and 320-2 include silicon dioxide, the dopant may include arsenic.

The first and second dielectric layers 320-1 and 320-2 containing dopants implanted through an ion implantation process may form a selector layer 350, which is illustrated in FIG. 3B.

Referring to FIG. 3B, the selector layer 350 may be formed over the first electrode layer 310.

Subsequently, a second electrode layer 360 may be formed over the selector layer 350.

In some implementations, during the ion implantation process of the dopant, the dopant ions may collide with the metal-containing pattern 330, scattering and incorporating the metal ions of the metal-containing pattern 330 into the first and second dielectric layers 320-1 and 320-2. As a result, the selector layer 350 may further include metal ions incorporated through a scattering method in addition to the implanted dopant. The metal ions in the selector layer 350 may be represented by M^{X+}. In this way, when the metal-containing pattern 330 is formed in advance in or over the first and second dielectric layers 320-1 and 320-2, the concentration or distribution of the metal ions in the selector layer 350 may be easily controlled. The following mechanism can enable a uniform integration of the metal ions into the selector layer. The concentration or distribution of the metal ions may be controlled by controlling the location or number of the metal-containing patterns 330. For example, when the number of depositions of the dielectric layer is deposited increases and accordingly the number of formations of the metal-containing pattern increases, the distribution of the metal ions may become uniform as the concentration of the metal ions is increased.

In this way, the metal ions can be uniformly distributed at an appropriate concentration in the selector layer 350, thereby improving the switching characteristics, for example, the switching characteristics can be improved by lowering the forming voltage/threshold voltage of the selector layer 350. In addition, since the scattering of the metal ions in the first electrode layer 310 is unnecessary, there is no need to increase the ion implantation energy when the dopant is implanted. In other words, relatively low ion implantation energy may be used, and accordingly, it is possible to secure the thickness of the selector layer 350, the thickness of the first electrode layer 310, and a uniform and clear interface between the selector layer 350 and the first electrode layer 310. Since the metal ions of the selector layer 350 do not originate from the first electrode layer 310, they may be the same as or different from the metal ions of the first electrode layer 310.

In some embodiments of the disclosed technology, during the ion implantation process of the dopant, the metal-containing pattern 330 may be removed entirely, and may exist in the selector layer 350 in the form of metal ions. However, the disclosed technology is not limited to this, and the traces of the metal-containing pattern 330 may remain in the selector layer 350. This will be described with reference to FIG. 3C.

FIG. 3C is a cross-sectional view illustrating a selector unit based on another embodiment of the disclosed technology.

Referring to FIG. 3C, traces 335 of the metal-containing pattern 330 may be present in the selector layer 350. The traces 335 of the metal-containing pattern 330 may be fine particles whose size is smaller than that of the metal-containing pattern 330, and the traces 335 of the metal-containing pattern 330 may also be referred to as metal-containing particles.

The traces 335 may show a relatively high concentration in the area where the metal-containing pattern 330 used to be disposed. In some implementations, the concentration of the traces 335 may be maximal in the interface between the above-described first dielectric layer 320-1 and the second dielectric layer 320-2 (e.g., corresponding to the dotted line in FIG. 3C), or the interface between the selector layer 350 and the second electrode layer 360. For example, the concentration of the traces 335 may correspond to different locations, such as a specific point between the interface (e.g., corresponding to the dotted line in FIG. 3C) and the interface between the selector layer 350 and the second electrode layer 360, or a specific point between the interface (e.g., corresponding to the dotted line in FIG. 3C) and the interface between the first electrode layer 310 and the selector layer 350. The concentration profile of the traces 335 is shown on the right side of the selector layer 350 by way of example.

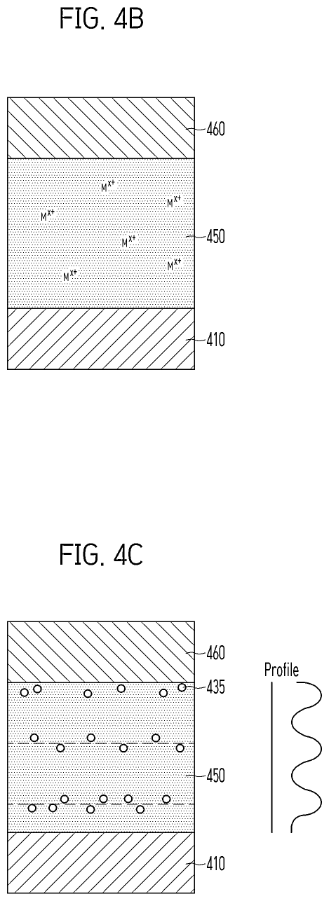

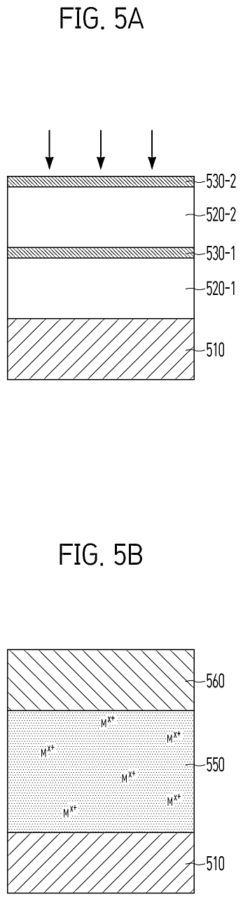

FIGS. 4A and 4B are cross-sectional views illustrating a method for forming a selector unit and the selector unit formed using the method based on another embodiment of the disclosed technology. The explanation below will focus on what is different from the embodiment of FIGS. 3A and 3B described above.

Referring to FIG. 4A, a first electrode layer 410 may be provided.

Subsequently, a buffer layer 440 may be formed over the first electrode layer 410. The buffer layer 440 may function to prevent or reduce the loss of the first electrode layer 410 which occurs as the dopant ions reach the first electrode layer 410 during the ion implantation process of the dopant, as will be discussed below. Furthermore, the buffer layer 440 may be interposed between the first electrode layer 410 and the first dielectric layer 420-1, as will be discussed below, to improve adhesion characteristics between them. The buffer layer 440 may be formed selectively. In other words, the buffer layer 440 may be omitted. The buffer layer 440 may include diverse materials containing non-conductive elements, such as SiB, SiCN, SiO₂, SiN, SiBN, or a combination thereof. The buffer layer 440 may include a non-conductive element in order not to involve in the operation of the selector layer even though the element of the buffer layer 440 is present in the selector layer that is formed in the subsequent process. For example, the buffer layer 440 may include silicon nitride (SiN).

Subsequently, a metal-containing pattern 430 may be formed over the buffer layer 440. In some implementations, the formation of the metal-containing pattern 430 over the buffer layer 440 may also be optional.

Subsequently, the first dielectric layer 420-1, the metal-containing pattern 430, the second dielectric layer 420-2, and the metal-containing pattern 430 may be sequentially formed over the buffer layer 440 where the metal-containing pattern 430 is formed.

Subsequently, a dopant may be implanted into the buffer layer 440 where the metal-containing pattern 430 is formed, and the first and second dielectric layers 420-1 and 420-2.

The first and second dielectric layers 420-1 and 420-2 containing dopants implanted through an ion implantation process may form a selector layer 450, which is illustrated in FIG. 4B.

Referring to FIG. 4B, the selector layer 450 may be formed over the first electrode layer 410.

Subsequently, a second electrode layer 460 may be formed over the selector layer 450.

During the ion implantation process of the dopant, the dopant ions may collide with the metal-containing pattern 430, the metal ions of the metal-containing pattern 430 are controllably scattered to be uniformly incorporated into the first and second dielectric layers 420-1 and 420-2. As a result, the selector layer 450 may further include the metal ions that are scattered and incorporated in addition to the implanted dopant.

Furthermore, during the ion implantation process of the dopant, the buffer layer 440 may be mixed with the first and second dielectric layers 420-1 and 420-2, and thus the elements of the buffer layer 440 may be included in the selector layer 450. In other words, the selector layer 450 may include all of the elements of the first and second dielectric layers 420-1 and 420-2 and the elements of the buffer layer 440. For example, when the first and second dielectric layers 420-1 and 420-2 include silicon dioxide and the buffer layer 440 includes silicon nitride, the selector layer 450 may include silicon, oxygen, and nitrogen.

In an embodiment of the disclosed technology, during the ion implantation process of the dopant, the metal-containing pattern 430 may be broken and disappear entirely, and only the metal ions may exist in the selector layer 450. However, the disclosed technology is not limited to this, and the traces of the metal-containing pattern 430 may remain in the selector layer 450. This will be described below with reference to FIG. 4C.

FIG. 4C is a cross-sectional view illustrating a selector unit based on another embodiment of the disclosed technology.

Referring to FIG. 4C, traces 435 of the metal-containing pattern 430 may be present in the selector layer 450.

The traces 435 may show a relatively high concentration in the area where the metal-containing pattern 430 used to be disposed. For example, the concentration of the traces 435 may be maximal in the interface between the above-described first dielectric layer 420-1 and the second dielectric layer 420-2 (e.g., corresponding to the upper dotted line in FIG. 4C), the interface between the above-described buffer layer 440 and the first dielectric layer 420-1 (e.g., corresponding to the lower dotted line in FIG. 4C), or the interface between the selector layer 450 and the second electrode layer 460. The concentration profile of the traces 435 is shown on the right side of the selector layer 450 by way of example.

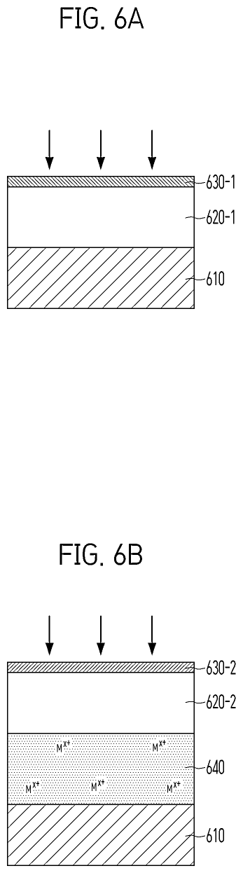

FIGS. 5A and 5B are cross-sectional views illustrating a method for forming a selector unit and the selector unit formed accordingly based on another embodiment of the disclosed technology. The explanation below will focus on what is different from the embodiment of FIGS. 3A and 3B explained above.

Referring to FIG. 5A, a first electrode layer 510 may be formed.

Subsequently, a first dielectric layer 520-1 may be formed over the first electrode layer 510.

Subsequently, a first metal-containing thin film 530-1 may be formed over the first dielectric layer 520-1. The first metal-containing thin film 530-1 may correspond to a source of metal ions, similarly to the above-described metal-containing pattern. The first metal-containing thin film 530-1 may have a thickness greater than 0 nm and equal to or smaller than 1 nm. In one example, the first metal-containing thin film 530-1 may have a thickness greater than 0 nm but equal to or smaller than approximately 0.5 nm. The first metal-containing thin film 530-1 within these ranges may be easily scattered and physically broken during the subsequent dopant ion implantation process. The first metal-containing thin film 530-1 may include a metal, such as tantalum (Ta), titanium (Ti), iridium (Ir), magnesium (Mg), tungsten (W), platinum (Pt) and the like, a metal oxide containing one or more of these metals, a metal nitride containing one or more of these metals, or an alloy containing two or more of these metals, and the first metal-containing thin film 530-1 may be formed through diverse deposition methods, such as PVD or ALD.

Subsequently, a second dielectric layer 520-2 may be formed over the first metal-containing thin film 530-1.

Subsequently, a second metal-containing thin film 530-2 may be formed over the second dielectric layer 520-2. The second metal-containing thin film 530-2 may be formed of the same material and thickness as those of the first metal-containing thin film 530-1. However, the disclosed technology is not limited thereto, and at least one among the material and thickness of the second metal-containing thin film 530-2 may be different from that of the first metal-containing thin film 530-1.

As discussed above, in some embodiments, the two dielectric layers 520-1 and 520-2 are formed and after the process of forming the dielectric layers 520-1 and 520-2, the two metal-containing thin films 530-1 and 530-2 are respectively formed over the dielectric layers 520-1 and 520-2, but the disclosed technology is not limited thereto. In another embodiment of the disclosed technology, a plurality of dielectric layers may be formed over the first electrode layer 510, and a metal-containing thin film may be formed over each of the dielectric layers after the process of forming each of the dielectric layers. In some implementations, considering the concentration or distribution of the metal ions, the metal-containing thin film over a predetermined dielectric layer may be omitted, if necessary. In other words, when the first to N^{th} dielectric layers are formed over the first electrode layer 510 (where N is a natural number equal to or greater than 2), the metal-containing thin film may be formed over each of the first to N^{th} dielectric layers. However, the metal-containing thin film may not be formed over a t^{th} dielectric layer among the first to N^{th} dielectric layers (where t is an arbitrary number equal to or greater than 2 and equal to or smaller than N), but may be formed only over each of the remaining dielectric layers. In any case, the metal-containing thin film may be formed to be disposed between at least two neighboring dielectric layers among the dielectric layers. For example, the first metal-containing thin film 530-1 may be maintained and the second metal-containing thin film 530-2 may be omitted.

Subsequently, a dopant may be implanted into a stacked structure of the first dielectric layer 520-1, the first metal-containing thin film 530-1, the second dielectric layer 520-2, and the second metal-containing thin film 530-2.

The first dielectric layer 520-1, the first metal-containing thin film 530-1, the second dielectric layer 520-2, and the second metal-containing thin film 530-2 containing the dopant implanted through an ion implantation process may form a selector layer 550, which is illustrated in FIG. 5B.

Referring to FIG. 5B, the selector layer 550 may be formed over the first electrode layer 510.

Subsequently, a second electrode layer 560 may be formed over the selector layer 550.

During the ion implantation process of the dopant, the dopant ions may collide with the first and second metal-containing thin films 530-1 and 530-2, and thus the metal ions of the first and second metal-containing thin films 530-1 and 530-2 are controllably scattered and uniformly incorporated into the first and second dielectric layers 520-1 and 520-2. As a result, the selector layer 550 may further include metal ions incorporated through a scattering method in addition to the implanted dopant.

In some embodiments of the disclosed technology, during the ion implantation process of the dopant, the first and second metal-containing thin films 530-1 and 530-2 may be removed entirely, and may exist in the selector layer 550 in the form of metal ions. However, the disclosed technology is not limited to this, and traces of the first and second metal-containing thin films 530-1 and 530-2 may remain in the selector layer 550. Since the selector layer 550 having the traces may be the same or similar to what is described in FIG. 3C, detailed description on it will be omitted.

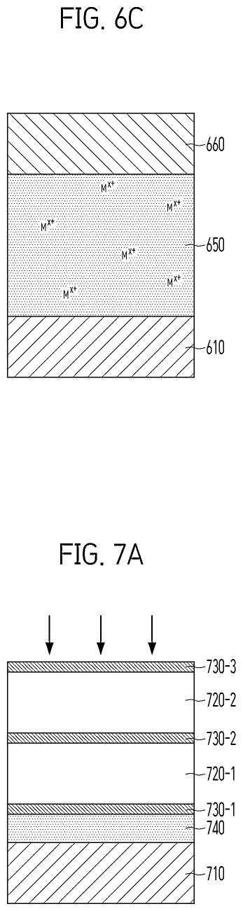

FIGS. 6A and 6A are cross-sectional views illustrating a method for forming a selector unit and the selector unit formed accordingly based on another embodiment of the disclosed technology. The explanation below will focus on the difference from the embodiment of FIGS. 5A and 5B described above.

Referring to FIG. 6A, a first electrode layer 610 may be provided.

Subsequently, a first dielectric layer 620-1 may be formed over the first electrode layer 610.

Subsequently, a first metal-containing thin film 630-1 may be formed over the first dielectric layer 620-1.

Subsequently, a primary dopant may be implanted into the stacked structure of the first dielectric layer 620-1 and the first metal-containing thin film 630-1. When the primary dopant is implanted, the dopant ions may collide with the first metal-containing thin film 630-1, the metal ions of the first metal-containing thin film 630-1 are controllably scattered and uniformly incorporated into the first dielectric layer 620-1. As a result, an initial selector layer 640 as illustrated in FIG. 6B may be formed.

Referring to FIG. 6B, a second dielectric layer 620-2 may be formed over the initial selector layer 530, and a second metal-containing thin film 630-2 may be formed over the second dielectric layer 620-2.

Subsequently, a secondary dopant may be implanted into the stacked structure of the second dielectric layer 620-2 and the second metal-containing thin film 630-2. When the secondary dopant is implanted, the dopant ions may collide with the second metal-containing thin film 630-2, the metal ions of the second metal-containing thin film 630-2 are controllably scattered and uniformly incorporated into the second dielectric layer 620-2. Depending on the ion implantation energy, when the secondary dopant is implanted, the dopant ions may also be incorporated into the initial selector layer 640. As a result, the selector layer 650 as illustrated in FIG. 6C may be formed.

Subsequently, a second electrode layer 660 may be formed over the selector layer 650.

Some embodiments based on FIGS. 6A and 6A may be different from the embodiments based on FIGS. 5A and 5B in that a dopant ion implantation process is additionally performed in the middle of the process of stacking the dielectric layers and the metal-containing thin films. For example, in the embodiment of FIGS. 5A and 5B, after alternately stacking a plurality of dielectric layers and a plurality of metal-containing thin films, a dopant may be implanted into the stacked structure. On the other hand, in some embodiments of the disclosed technology based on FIGS. 6A and 6A, after forming one or more dielectric layers among a plurality of dielectric layers and forming a metal-containing thin film over each of the one or more dielectric layers, a dopant ion implantation may be additionally performed. In some embodiments of the disclosed technology based on FIGS. 6A and 6A, compared to the embodiments based on FIGS. 5A and 5B, it is possible to implant a dopant and scatter metal ions even with a smaller ion implantation energy. Accordingly, it may be possible to secure the thickness of the selector layer 650, the thickness of the first electrode layer 610, and a uniform and clear interface between the selector layer 650 and the first electrode layer 610.

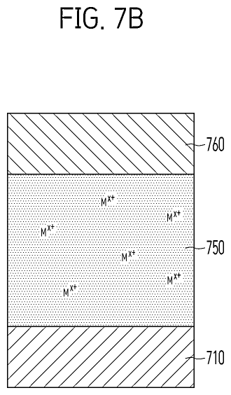

FIGS. 7A and 7B are cross-sectional views illustrating a method for forming a selector unit and the selector unit formed accordingly based on another embodiment of the disclosed technology. The explanation below will focus on what is different from the embodiment of FIGS. 5A and 5B described above.

Referring to FIG. 7A, a first electrode layer 710 may be provided.

Subsequently, a buffer layer 740 may be formed over the first electrode layer 710. The buffer layer 740 may be formed selectively. In other words, the buffer layer 740 may be omitted. The buffer layer 740 may include diverse materials containing non-conductive elements, such as SiB, SiCN, SiO₂, SiN, SiBN, or a combination thereof.

Subsequently, a first metal-containing thin film 730-1 may be formed over the buffer layer 740. The formation of the first metal-containing thin film 730-1 over the buffer layer 740 may also be optional.

Subsequently, a first dielectric layer 720-1, a second metal-containing thin film 730-2, a second dielectric layer 720-2, and a third metal-containing thin film 730-3 may be sequentially formed over the buffer layer 740.

Subsequently, a dopant may be implanted into a stacked structure of the buffer layer 730, the first metal-containing thin film 730-1, the first dielectric layer 720-1, the second metal-containing thin film 730-2, the second dielectric layer 720-2, and the third metal-containing thin film 730-3.

The buffer layer 740, the first metal-containing thin film 730-1, the first dielectric layer 720-1, the second metal-containing thin film 730-2, the second dielectric layer 720-2, and the third metal-containing thin film 730-3 containing the dopant implanted through an ion implantation process may form a selector layer 750, which is illustrated in FIG. 7B.

Referring to FIG. 7B, the selector layer 750 may be formed over the first electrode layer 710.

Subsequently, a second electrode layer 760 may be formed over the selector layer 750.

During the ion implantation process of the dopant, the dopant ions may collide with the first to third metal-containing thin films 730-1, 730-2 and 730-3, thereby scattering and incorporating the metal ions of the first to third metal-containing thin films 730-1, 730-2 and 730-3 into the first and second dielectric layers 720-1 and 720-2. As a result, the selector layer 750 may further include the metal ions incorporated through a scattering process in addition to the implanted dopant.

Furthermore, during the ion implantation process of the dopant, the buffer layer 740 may be mixed with the first and second dielectric layers 720-1 and 720-2 so that the elements of the buffer layer 740 are also included in the selector layer 750.

In some embodiments of the disclosed technology, during the ion implantation process of the dopant, the first to third metal-containing thin films 730-1, 730-2 and 730-3 may be broken and disappear entirely, and may exist in the selector layer 750 in the form of metal ions. However, the disclosed technology is not limited to this, and the traces of the first to third metal-containing thin films 730-1, 730-2 and 730-3 may remain in the selector layer 750. Since the selector layer 750 having the traces may be the same or similar to what is described in FIG. 4C, detailed description on it will be omitted.

In some embodiments of the disclosed technology, the characteristics of a selector may be secured.

Only a few embodiments and examples are described. Enhancements and variations of the disclosed embodiments and other embodiments can be made based on what is described and illustrated in this patent document.

What is claimed is:

1. A method for fabricating a semiconductor device, comprising:
forming a first electrode layer;
forming, over the first electrode layer, a plurality of dielectric layers with one or more metal-containing patterns or one or more metal-containing thin films being disposed between at least two neighboring dielectric layers of the plurality of dielectric layers; and
forming a selector layer that exhibits threshold switching characteristics for switching between different states of electrical conductivity in response to a voltage applied across the selector layer by performing a first implanting process to implant a dopant into the at least two neighboring dielectric layers including or in contact with the one or more metal-containing patterns or the one or more metal-containing thin films.

2. The method of claim 1, wherein the dopant is configured to form a trap site that provides a passage for migration of conductive carriers in the plurality of dielectric layers.

3. The method of claim 1, wherein while implanting the dopant, metal ions of the one or more metal-containing patterns or the one or more metal-containing thin films are scattered and incorporated into the plurality of dielectric layers with a predetermined uniformity.

4. The method of claim 1, wherein the one or more metal-containing patterns have at least one of a dot shape and a bar shape.

5. The method of claim 1, wherein a maximum length of the metal-containing pattern ranges from 1 to 10 nanometers.

6. The method of claim 1, wherein a thickness of the metal-containing thin film is greater than 0 nm, and equal to or smaller than 1 nm.

7. The method of claim 1, wherein:
the plurality of dielectric layers includes silicon dioxide; and
the dopant includes arsenic.

8. The method of claim 1, wherein the one or more metal-containing patterns or the one or more metal-containing thin films include a metal that is different from the dopant and the first electrode layer.

9. The method of claim 1, further comprising:
after forming the first electrode layer and before forming the plurality of dielectric layers,
forming a buffer layer containing a non-conductive element over the first electrode layer.

10. The method of claim 9, wherein the buffer layer includes silicon nitride.

11. The method of claim 9, wherein while implanting the dopant, the buffer layer is mixed with the plurality of dielectric layers.

12. The method of claim 9, wherein the one or more metal-containing patterns or the one or more metal-containing thin films are further formed over the buffer layer.

13. The method of claim 1, wherein the one or more metal-containing patterns or the one or more metal-containing thin films are further formed over an uppermost dielectric layer of the plurality of dielectric layers.

14. The method of claim 1, further comprising:
after forming one or more dielectric layers of the plurality of dielectric layers, and the one or more metal-containing thin films over each of the one or more dielectric layers of the plurality of dielectric layers, performing a second implanting process to implant a dopant into the plurality of dielectric layers.

15. The method of claim 1, wherein while implanting the dopant, a size of the metal-containing pattern is decreased.

16. The method of claim 1, wherein while implanting the dopant, the metal-containing thin film is broken.

17. A semiconductor device, comprising:
a first electrode layer; and
a selector layer disposed over the first electrode layer and configured to exhibit threshold switching characteristics for switching between different states of electrical conductivity in response to a voltage applied across the selector layer with respect to a threshold voltage, and,
wherein the selector layer includes:
a dielectric layer;
a dopant configured to form a trap site that provides a passage for conductive carriers in the dielectric layer; and
metal ions incorporated into the dielectric layer.

18. The semiconductor device of claim 17, wherein:
the selector layer further includes metal-containing particles in the dielectric layer; and
a metal contained in the metal-containing particles corresponds to a metal of the metal ions.

19. The semiconductor device of claim 18, wherein:
the dielectric layer includes a plurality of dielectric layers; and
a concentration of the metal-containing particles is maximum at an interface between at least two neighboring dielectric layers of the plurality of dielectric layers.

20. The semiconductor device of claim 17, wherein a metal of the metal ions is different from the dopant and a metal of the first electrode layer.
